(19) United States
(12) Patent Application Publication
(10) Pub. No.: US 2025/0300075 A1
(43) Pub. Date: Sep. 25, 2025

(54) BACKSIDE MONOLITHIC 3D INTEGRATION

(71) Applicant: INTERNATIONAL BUSINESS MACHINES CORPORATION, Armonk, NY (US)

(72) Inventors: Fabio Carta, Pleasantville, NY (US); Tao Li, Slingerlands, NY (US); Ruilong Xie, Niskayuna, NY (US); Nicolas Jean Loubet, Guilderland, NY (US)

(21) Appl. No.: 18/611,157

(22) Filed: Mar. 20, 2024

(51) Int. Cl. H01L 23/528; H01L 23/522; H01L 27/06; H01L 27/07; H01L 27/092; H01L 29/06; H01L 29/417; H01L 29/423; H01L 29/778; H01L 29/786

(52) U.S. Cl. CPC H01L 23/5283; H01L 23/5226; H10D 30/47; H10D 30/6729; H10D 30/6735; H10D 30/6757; H10D 62/121; H10D 84/811; H10D 84/85; H10D 88/00

(57) ABSTRACT

A semiconductor device includes a backside interconnect layer connected to a front end of line region by connections through a backside interlevel dielectric layer disposed between the backside interconnect layer and the front end of line region. A monolithic device includes a predominantly monocrystalline body disposed within the backside interlevel dielectric layer and contacted on a side opposite the front end of line region. The monolithic device is connected to a front end of line device by a connection through the backside interconnect layer.

### BACKGROUND

The present invention generally relates to semiconductor devices and processing methods, and more particularly to fabrication of a monolithic crystal island seeded from a monocrystalline region during a backside integration process.

Monolithically integrated devices are difficult to fabricate during back end of line (BEOL) processing as monocrystalline structures are not present. Further, many processes remove a monocrystalline substrate prior to backside processing making it difficult or impossible to add a monolithic device on a backside of the device. Methods to crystallize polycrystalline or amorphous semiconductor material, e.g., using laser grain filter techniques, suffer from random orientations which are detrimental to device uniformity.

Therefore, a need exists for integration of a backside monolithic device that includes a reliable monocrystalline structure that does not suffer from random crystal orientations.

### SUMMARY

In accordance with an embodiment of the present invention, a semiconductor device includes a backside interconnect layer connected to a front end of line region by connections through a backside interlevel dielectric layer disposed between the backside interconnect layer and the front end of line region. A monolithic device includes a predominantly monocrystalline body disposed within the backside interlevel dielectric layer and contacted on a side opposite the front end of line region. The monolithic device is connected to a front end of line device by a connection through the backside interconnect layer.

In other embodiments, the monolithic device can include a field effect transistor. The field effect transistor can be a planar device (e.g., two-dimensional channel device). The monolithic device can include a diode. The front end of line device and the monolithic device can be vertically aligned but on different levels. The seed material can be in contact with source and drain regions. The seed material can be a same material and structure as the monocrystalline body of the monolithic device.

In accordance with another embodiment of the present invention, a semiconductor device includes a front end of line region including field effect transistors and defining a frontside and a backside, opposite the frontside. A backside interconnect layer on the backside is connected to the front end of line region by connections through a backside interlevel dielectric layer disposed between the backside interconnect layer and the front end of line region. A monolithic device includes a predominantly monocrystalline body disposed within the backside interlevel dielectric layer. The monolithic device has the body contacted by a contact on a side opposite the front end of line region. The contact connects to the backside interconnect layer and is further connected to a source/drain region in the front end of line region. A through via traverses the front end of line region and connects to the monolithic device through the backside interconnect layer on the backside.

In other embodiments, the monolithic device can include a field effect transistor. The field effect transistor can be planar. The monolithic device can include a diode. One of the field effect transistors of the front end of line region can include a logic device and the monolithic device can be vertically aligned with the logic device but disposed on a different layer. The seed material can be in contact with source and drain regions. The seed material can be a same material and structure as the monocrystalline body of the monolithic device.

In accordance with another embodiment of the present invention, a semiconductor device includes a front end of line region including field effect transistors, the front end of line region defining a frontside and a backside, opposite the frontside. The field effect transistors of the front end of line region include a source/drain region in contact with a seed material having a width. A monolithic device includes a predominantly monocrystalline body disposed in a backside interlevel dielectric layer between a backside interconnect layer and the front end of line region. The monolithic device has a width greater than the width of the seed material.

In other embodiments, the field effect transistors of the front end of line region can include a logic device and the monolithic device is vertically aligned with the logic device. The seed material can be in contact with source and drain regions on the backside. The seed material can have a same material and structure as the monocrystalline body of the monolithic device. The monolithic device can include a field effect transistor. The field effect transistor can be planar. The monolithic device can include a diode.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 shows two cross-sectional views which are offset relative to one another by a depth relative to a plane of the page for a wafer having a semiconductor device fabricated thereon, in accordance with an embodiment of the present invention;

FIG. 2 shows the two cross-sectional views having a substrate removed but leaving seed material in place, in accordance with an embodiment of the present invention;

FIG. 3 shows the two cross-sectional views having the seed material exposed through a dielectric layer, in accordance with an embodiment of the present invention;

FIG. 4 shows the two cross-sectional views having an amorphous phase material deposited in contact with the seed material and over the dielectric layer, in accordance with an embodiment of the present invention;

FIG. 5 shows the two cross-sectional views having the amorphous phase material patterned on the dielectric layer, where a pattern of the amorphous phase material permits formation of large islands to be employed as one or more devices, in accordance with an embodiment of the present invention;

FIG. 6 shows the two cross-sectional views having the amorphous phase material annealed to form predominantly monocrystalline material, where the predominantly monocrystalline material can be employed to form one or more monolithic devices, in accordance with an embodiment of the present invention;

FIG. 7 shows the two cross-sectional views having a passivation layer formed and a dielectric layer deposited, in accordance with an embodiment of the present invention;

FIG. 8 shows the two cross-sectional views having breakdown voltage via holes opened up to expose through vias, in accordance with an embodiment of the present invention;

FIG. 9 shows the two cross-sectional views having the breakdown voltage via formed, in accordance with an embodiment of the present invention; and

FIG. 10 shows the two cross-sectional views having monolithic devices and their connections formed, in accordance with an embodiment of the present invention.

### DETAILED DESCRIPTION

In accordance with embodiments of the present invention, devices and methods are described which provide a way of crystallizing semiconductor islands by seeding from a monocrystalline region provided during backside integration processes. This enables single crystal islands to have a precise and uniform orientation throughout a wafer providing a good substrate for device integration in back end of the line regions.

Integration of monolithic devices is extremely useful in proximity to power lines at a back end of line as the monolithic devices can provide many useful applications such as, e.g., power gating, voltage regulation, electrostatic discharge (ESD) diodes, among others.

In an embodiment, a crystal island is formed on a backside of the wafer that includes at least a via connecting to a single portion of a monocrystalline substrate used for front end of line (FEOL) integration. The crystal island is employed to form a semiconductor device that includes a transistor at the backside of the wafer. In an embodiment, a transistor (e.g., a monolithic device) has a crystal film provided with a gate on top and planar source/drain (S/D) regions formed on each side of the crystal film. The gate is connected to a backside interconnect in a backside interconnect region through a backside via (BSV). At least one of the S/D regions is connected to the backside interconnect through the backside via (BSV).

An amorphous phase portion can be employed to form an extended portion of the crystal film so that one or more monolithic devices can be fabricated. The monolithic devices can be positioned in proximity (e.g., under or vertically aligned with) a logic device. The logic device can be included in the FEOL processing. S/D regions of the logic device can be connected to a backside interconnect layer by way of backside vias or contacts, breakdown voltage vias and through vias.

In other embodiments, methods of forming a semiconductor device include flipping a substrate, after front end of the line (FEOL), middle end of the line (MOL), back end of the line (BEOL) processing and bonding a carrier wafer on a frontside of a wafer. Then, a substrate is removed from a backside of the wafer, stopping on an etch stop layer. The etch stop layer is then removed, and a remainder of semiconductor layer is removed except for seed material. Patterning of logic regions is performed to form logic devices. A backside interlevel dielectric layer is formed and planarized.

A trench is opened to expose monocrystalline material of a seed material buried within a structure of the wafer. The trench is filled with amorphous material that matches the monocrystalline material of the seed material. In an embodiment, the amorphous material can include, e.g., amorphous Si (a-Si) and the monocrystalline material can include, e.g., Si. A laser crystallization can be performed on the amorphous material using the monocrystalline material of the seed material. The amorphous material is crystallized by the laser and provides a pristine crystallographic structure matching the monocrystalline material to produce a uniform crystallographic structure throughout.

Processing continues with patterning vias (e.g., BSV) and interconnects. Additional dielectric is deposited to backfill the backside interlevel dielectric layer and is planarized. Active regions are patterned and gate structures formed for monolithic devices, which can include any type of semiconductor device including transistors, diodes, etc. The active regions can be subjected to a backside S/D implantation process. Processing continues to complete the one or more monolithic devices.

Crystallizing a seed material having a monocrystalline region left during the backside integration process enables the formation of a transistor in backside interconnect region processing, which can be employed as a switch for power rail connections, off chip connections, electrostatic discharge functions or any other useful purpose.

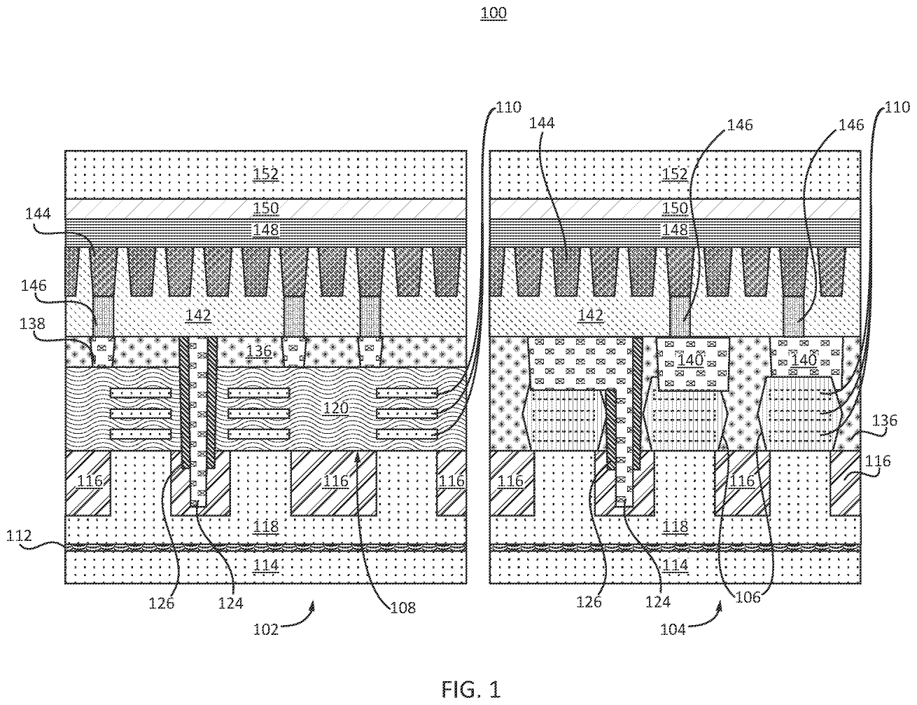

Referring now to the drawings in which like numerals represent the same or similar elements and initially to FIG. 1, devices and methods for manufacturing nanosheet field effect transistors (FETs), with a monolithic device formed in back end of line layers, are shown in accordance with embodiments of the present invention. A wafer 100 includes a substrate 114, which can include one or more layers on which semiconductor processing is performed. FIG. 1 depicts two offset views 102 and 104 for different regions of the wafer 100. View 102 shows a cross-section view taken longitudinally along a gate line 108. View 104 shows a cross-section view taken transversely to source/drain regions 106. Transistor channels 110 are formed at intersections of lines for source/drain regions 106 and the gate line 108. Views 102 and 104 are parallel but offset relative to the plane of the page.

The substrate 114 can include any suitable substrate structure, e.g., a bulk semiconductor, a semiconductor-on-insulator (SOI) substrate, etc., and preferably includes a monocrystalline semiconductor. In one example, the substrate 114 can include a silicon-containing material. Illustrative examples of Si-containing materials suitable for the substrate 114 can include, but are not limited to, Si, SiGe, SiGeC, SiC and multi-layers thereof. Although silicon is the predominantly used semiconductor material in wafer fabrication, alternative semiconductor materials can be employed as additional layers, such as, but not limited to, germanium, gallium arsenide, gallium nitride, silicon germanium, cadmium telluride, zinc selenide, etc.

An etch stop layer 112 is formed on the substrate 114. The etch stop layer 112 can include an epitaxially grown crystal structure. The etch stop layer 112 includes a material that permits the selective etching and removal of the substrate 114 in later steps. In an embodiment, the etch stop layer 112 includes SiGe, although depending on the material of the substrate 114, other materials can be selected, e.g., SiGeC, SiC, etc.

A semiconductor layer 118 is epitaxially grown on the etch stop layer 112. The semiconductor layer 118 can include a same material as the substrate 114, although other semiconductor materials can be employed, e.g., SiGe, SiGeC, SiC, etc. The semiconductor layer 118 includes a monocrystalline structure that can include a perfect crystal or predominantly perfect crystal. The material or portion thereof of the semiconductor layer 118 will be employed as a seed material for later formed monolithic transistor devices.

In illustrative examples described here, a nanosheet stack includes a stack of alternating semiconductor materials. In an embodiment, the nanosheet stack includes nanosheets (NS) that can include semiconductor layers used to form transistor channels 110. The transistor channels 110 can include Si, although other semiconductor materials can be employed.

The semiconductor layer 118 can be etched to form shallow trenches therein. Shallow trench isolation (STI) regions or STI 116 are formed in the shallow trenches. STI 116 can be formed by depositing dielectric material, such as, e.g., SiO₂, SiOₓN_{y}, SiCO or other suitable compounds in the shallow trenches. STI 116 can be deposited using chemical vapor deposition (CVD), although other deposition methods can be employed. The STI can be leveled off by a recess etch.

A gate dielectric layer (not shown) is deposited to cover the transistor channels 110. The gate dielectric layer can be formed by, e.g., chemical vapor deposition (CVD) or atomic layer deposition (ALD). Suitable examples of oxides that can be employed for the gate dielectric layer can include, but are not limited to: Al₂O₃, ZrO₂, HfO₂, Ta₂O₃, TiO₂ and combinations thereof.

A gate conductive material 120 is formed over the gate dielectric layer and fills spaces between the semiconductor layers of the transistor channels 110. The gate conductive material 120 can include at least one gate conductor. The gate conductive material 120 can include any conductive metal including, but not limited to W, Ni, Ti, Mo, Ta, Cu, Pt, Ag, Au, Ru, Ir, Rh, and Re, and alloys that include at least one of these conductive materials. The gate conductive material 120 can include one or more layers of conductive materials. In one example, a second conductive material may be formed. When a combination of conductive elements is employed, an optional diffusion barrier material such as TaN or WN may be formed between the conductive materials. The gate conductive material 120 can be deposited by CVD, plasma enhanced CVD (PECVD), ALD or other suitable deposition process.

An epitaxial growth process is performed to form epitaxial regions for source/drain (S/D) regions 106. Source/drain regions 106 align on opposite sides of transistor channels 110 which are shown in dashed lines since the source/drain regions 106 are blocking the transistor channels 110 from view in view 104. Source/drain regions 106 can include Si or SiGe and include faceted surfaces when epitaxial growth is not confined. In an embodiment, the source/drain regions 106 can be designated as P-type or N-type devices.

The P-type and N-type devices can have materials selected accordingly. For example, if the source/drain regions 106 include N-type devices then the source/drain regions 106 can include Si. In another example, if the source/drain regions 106 include P-type devices then the source/drain regions 106 can include SiGe. The source/drain regions 106 can also be appropriately doped during their formation by epitaxial growth. For example, the source/drain regions 106 can be doped by introducing p dopants (e.g., B, Ga, etc.) during epitaxial formation. Similarly, the source/drain regions 106 can be doped by introducing n dopants (e.g., P, As, etc.) during epitaxial formation. In other embodiments, P-type and N-type devices can be formed adjacent to one another. Processing would include forming one device type and then the other device type by employing block masks to protect each device during the processing of the other.

An interlevel dielectric (ILD) 136 can be formed over the wafer 100. The ILD 136 can include any suitable material, e.g., selected from the group consisting of silicon containing materials such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, a-C: H.

Middle of the line (MOL) contacts 138, 140 are formed to make connections to the gate conductive material 120 and the source/drain regions 106, respectively, from a top or frontside of the wafer 100. Trenches or holes are formed in the ILD 136, which forms a top ILD. The trenches or holes expose the underlying conductive materials. Through vias 124 can be formed separately or concurrently with MOL contacts 138, 140. In an embodiments, the through via 124 extends from the frontside, e.g., the BEOL layer 148 or connectable position, to a depth into the FEOL below the S/D regions 106. In another embodiment, the through via 124 is integrally formed as an extension of an MOL contact.

For the through vias 124, trenches or holes are extended between a front side of the wafer 100 to a backside of the wafer 100 using a deep anisotropic etch, such as a reactive ion etch (RIE). The trenches are lined with a dielectric liner 126, which can include a conformally deposited nitride or oxide. The conformal deposition can include, e.g., CVD or ALD. The trenches are then extended by etching through the dielectric liner 126 into the STI 116 on the backside of the wafer 100.

In some embodiments, a silicide liner, such as, e.g., Ti, Ni, NiPt is deposited first in contact with source/drain regions 106 before formation of contacts 140, then a diffusion barrier can be formed in the trenches prior to a conductive fill. The diffusion barrier can include, e.g., TiN, TaN, or similar materials. For contacts 138 and/or through vias 124, a diffusion barrier can be formed in the trenches prior to a conductive fill.

The conductive fill for forming the contacts 138, 140 and/or through vias 124 is performed to fill the trenches on top of the diffusion barrier, if present. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, PECVD, ALD or any other suitable deposition method. The conductive fill is planarized, e.g., by chemical mechanical polishing (CMP), to form the contacts 138, 140 and through vias 124.

The contacts 138 are formed to make connections to the gate conductive material 120, and the contacts 140 make connections to the source/drain regions 106 from a top or frontside of the wafer 100. The through vias 124 extend across the front end of line (FEOL) devices (e.g., field effect transistors (FETs)).

BEOL processing can include forming another ILD 142 over the wafer 100. The ILD 142 can include any suitable material, e.g., as described with respect to ILD 136. The ILD 142 can be patterned to form via holes. The via holes can be lined with a diffusion barrier and can undergo a conductive fil and planarization (e.g., CMP) to form vias 146 across the wafer 100. The vias 146 can include similar materials as the contacts 138, 140. The ILD 142 is then extended and patterned to open up trenches for the formation of metal lines 144. Metal lines 144 (e.g., M1 metal lines) are formed by depositing a conductive material over the ILD 142 and planarizing a free surface of the wafer 100. The conductive material can include, e.g., Cu, Ru, Mo, Rh, W, Ir, and alloys or combinations of these and other conductive materials.

Processing continues with the formation of additional BEOL structures in BEOL layer 148, which can include metal structures and dielectric layers to complete the top side of a semiconductor device being fabricated. The BEOL layer 148 includes the metal lines 144 and vias 146 and provides electrical access to FETs formed in the FEOL region. A carrier wafer 152 can be bonded to the BEOL layer 148 by employing a bonding oxide 150 or other adhesive. The carrier wafer 152 provides support and transportability to the wafer 100 for further processing which includes flipping the wafer 100 and removing portions of a bottom or backside.

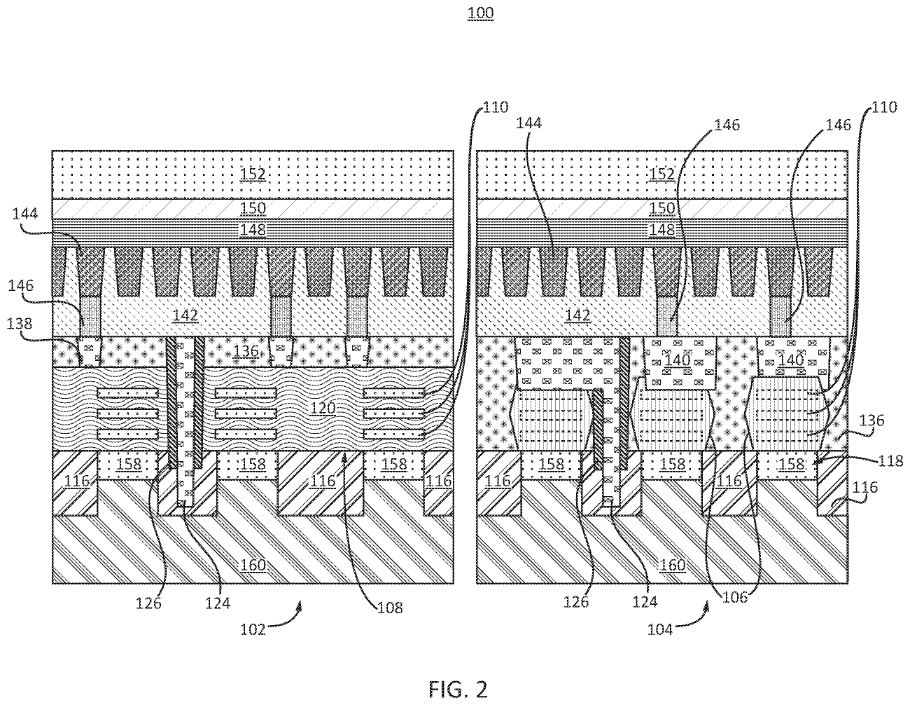

Referring to FIG. 2, to continue processing, the wafer 100 can be flipped to process features on the bottom or backside of the wafer 100. However, for clarity and consistency, the wafer 100 will be shown in the FIGS. in a same orientation as previously described with continued and consistent reference to bottom/top. The substrate 114 is removed from the backside of the wafer 100. The substrate 114 can be removed by an etch process that stops on the etch stop layer 112. In an alternate embodiment, a cleave process can be employed to propagate a crack to remove the substrate 114 at the etch stop layer 112.

The etch stop layer 112 is then removed by an etch process. In an alternate embodiment, a CMP process can be employed. With the removal of the etch stop layer 112, the semiconductor layer 118 is exposed. The semiconductor layer 118 is partially removed, or recessed, by an etch process that selectively removes the material of the semiconductor layer 118 relative to the STI 116. The etch process to remove portions of the semiconductor layer 118 can include a wet or dry etch. This partial etch back of the semiconductor layer 118 leaves a remnant to form seed material 158 in later steps. The seed material 158 includes monocrystalline or predominantly monocrystalline material which can be employed for seeding crystal growth, as will be described.

A dielectric layer 160 is deposited over the backside of the wafer 100. The dielectric layer 160 is formed over the seed material 158 and over the STI 116. The dielectric layer 160 includes a material, such as, e.g., a silicon oxide or other dielectric material as described for the ILD 136.

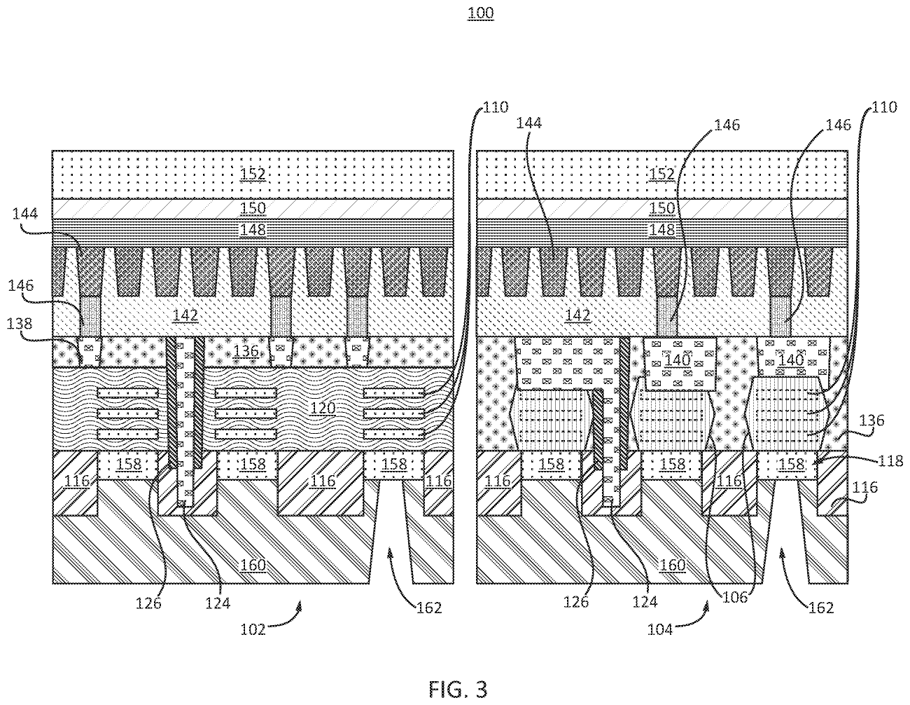

Referring to FIG. 3, openings 162 are formed to expose seed material 158 from the backside of the wafer 100. Openings 162 can be patterned using lithography and etched in accordance with an etch mask by an anisotropic etch process, e.g., RIE. There is no danger of damaging the source/drain regions 106 as the seed material 158 protects the source/drain regions 106 during the etch process. The openings 162 are formed at locations corresponding to a position where monolithic devices are to be formed.

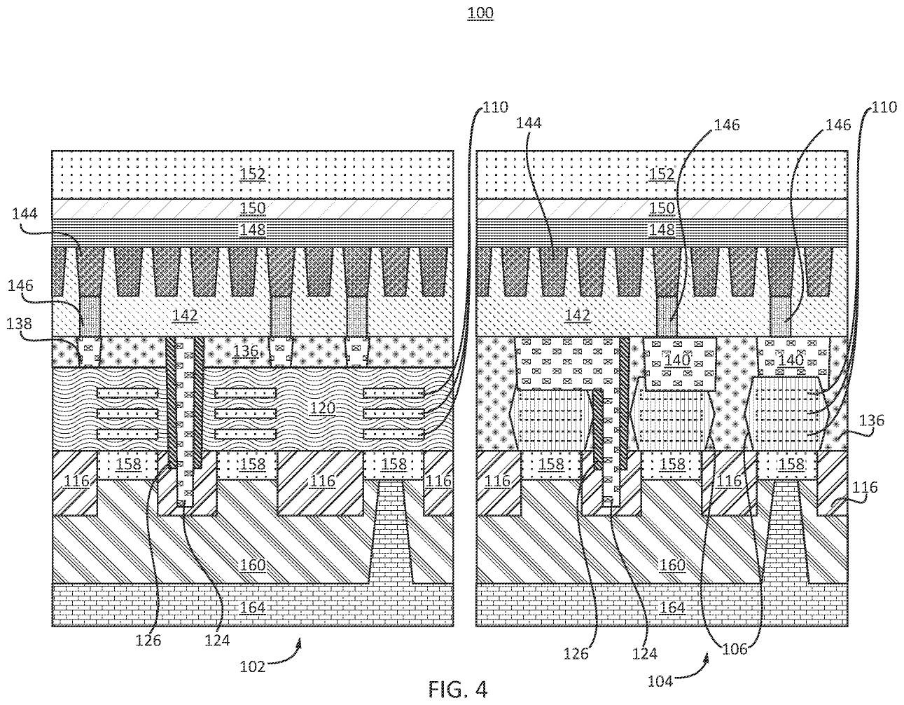

Referring to FIG. 4, an amorphous material 164 is deposited over the wafer 100 and fills the openings 162 (FIG. 3) to contact the seed material 158. The amorphous material 164 includes a same elemental material as the seed material 158. In an embodiment, the seed material 158 can include Si and the amorphous material 164 can include amorphous phase Si (a-Si). The amorphous material 164 can be deposited using, e.g., a PECVD or CVD process.

The amorphous material 164 can occupy a very large region on top of the dielectric layer 160. In this way, a monolithic device to be formed can include an extended size or multiple devices can be formed within the region. The monolithic devices to be formed can include planar FET devices (e.g., a two-dimensional (2D) or 2D channel devices), junctions, diodes or any other semiconductor device or devices.

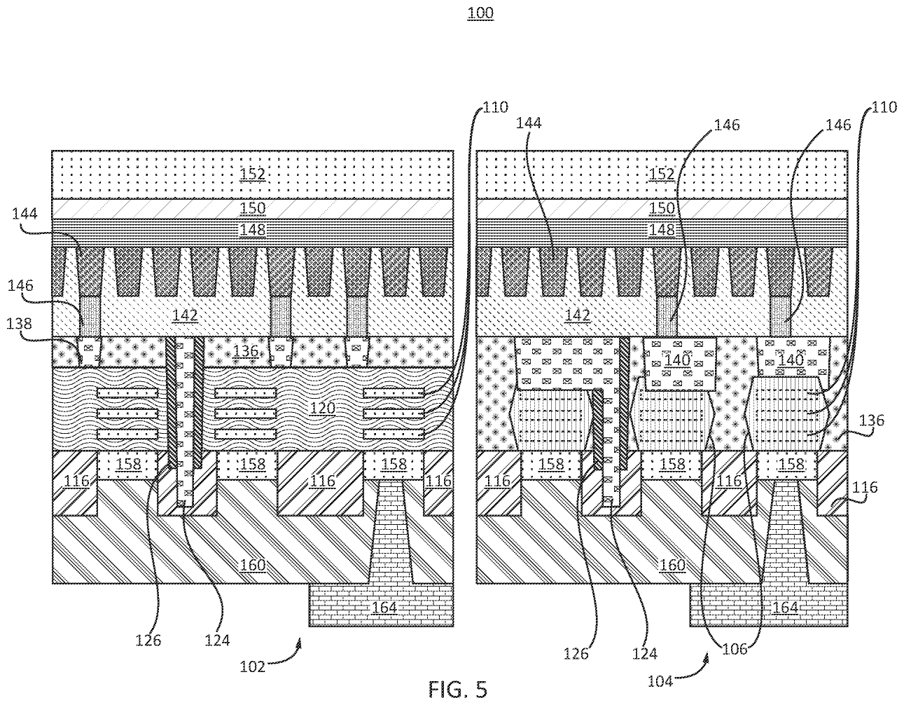

Referring to FIG. 5, the amorphous material 164 is patterned with a portion remaining in contact with the seed material 158. The amorphous material 164 can be patterned by forming a mask using a lithographic process and removing portions of the amorphous material 164 by etching, e.g., RIE, selective to the dielectric layer 160.

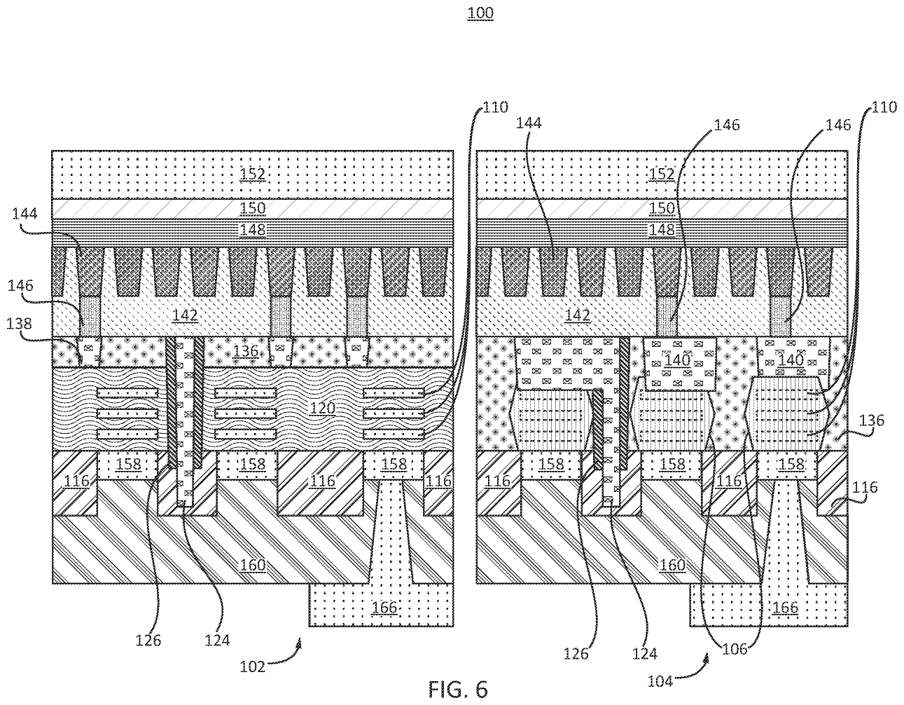

Referring to FIG. 6, the amorphous material 164 is thermally annealed to cause crystallization. In an embodiment, the amorphous material 164 can be exposed to a laser beam to heat the amorphous material 164. The laser beam can be focused to a given location for a duration sufficient to crystallize the amorphous material 164 in accordance with the seed material 158 to which the amorphous material 164 contacts. In this way, random crystal structures are avoided, and a monolithic or predominantly monolithic crystal structure results in forming a crystalized material 166. In an example, the crystalized material 166 includes crystallized Si, e.g., c-Si. Other anneal processes can also be employed. The crystalized material 166 seed material has a same material and structure as the seed material 158 after the anneal.

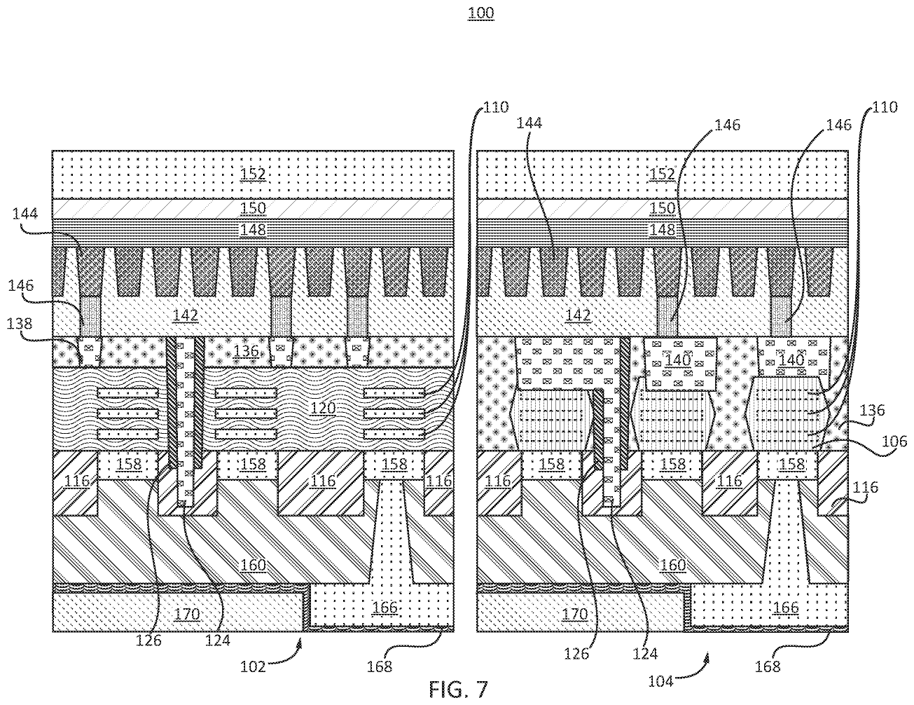

Referring to FIG. 7, a passivation layer 168 is deposited over the dielectric layer 160 and the crystallized material 166. The passivation layer 168 can be conformally deposited using a CVD process. The passivation layer 168 can include a nitride, such as, e.g., SiN. A backside dielectric layer 170 is then formed over the passivation layer 168. The backside dielectric layer 170 can be formed from a similar material and process as that described for the ILD 136. The passivation layer 168 and the backside dielectric layer 170 are planarized, e.g., by CMP, to level off a free surface of the wafer 100.

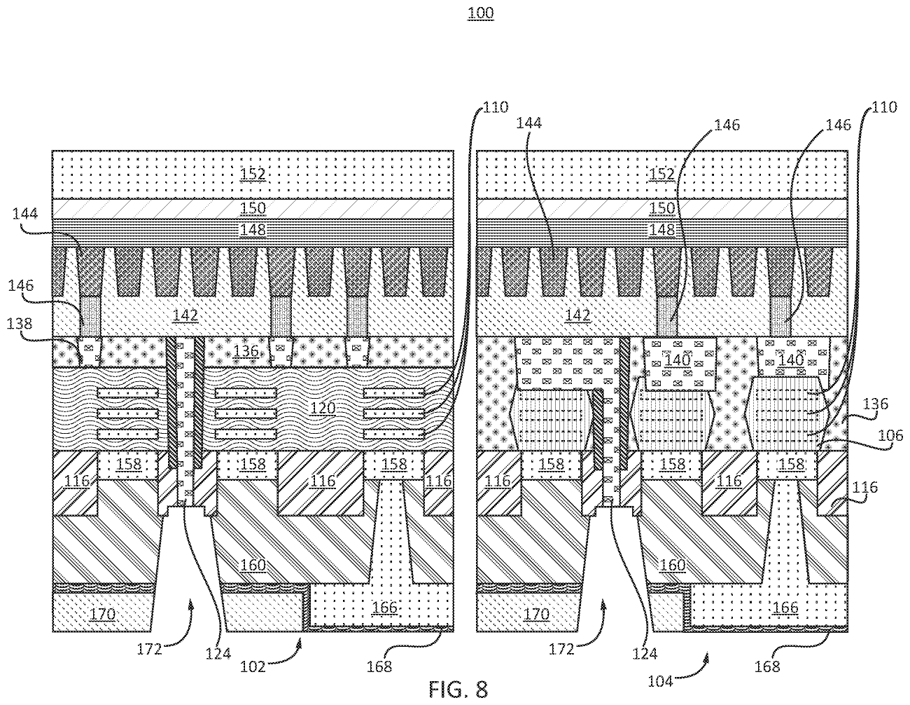

Referring to FIG. 8, backside contact openings 172 are formed through the backside dielectric layer 170, the passivation layer 168 and the dielectric layer 160 to access the STI 116. Etching continues to open up the STI 116 to expose the through via 124, as illustrated. Etching can be performed in accordance with photolithographic patterning techniques to create an etch mask to etch the backside contact openings 172 with an anisotropic etch., e.g., RIE.

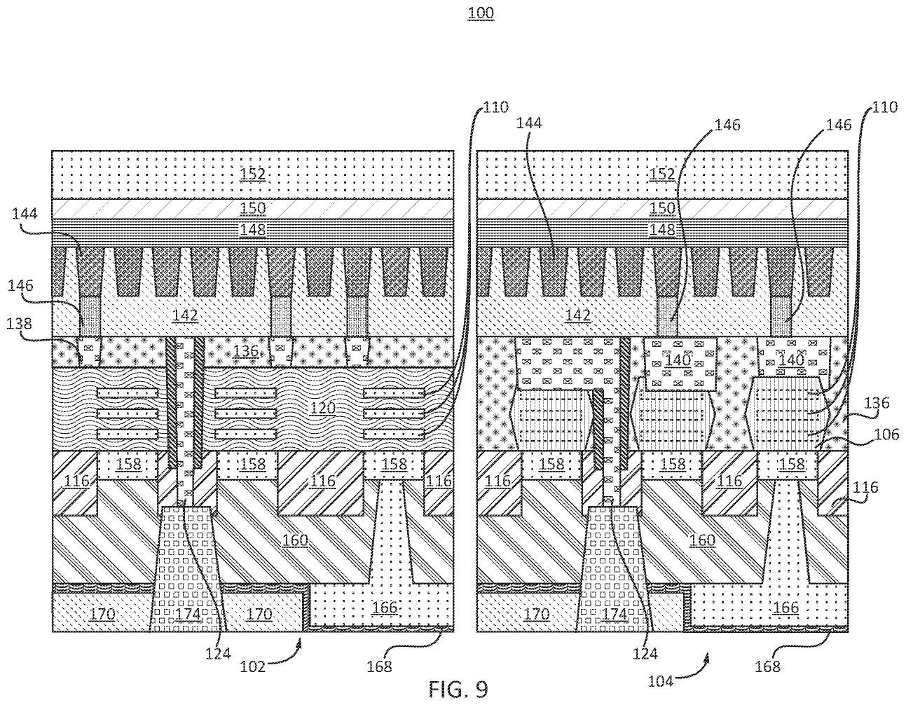

Referring to FIG. 9, a diffusion barrier (not shown) can be formed in the backside contact openings 172 (FIG. 8) prior to a conductive fill. The diffusion barrier can include, e.g., TiN, TaN, or similar materials. The conductive fill is performed to fill the backside openings 172 and make electrical contact with the through vias 124. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, PECVD, ALD or any other suitable deposition method. The conductive fill is planarized, e.g., by CMP, to form breakdown voltage vias 174.

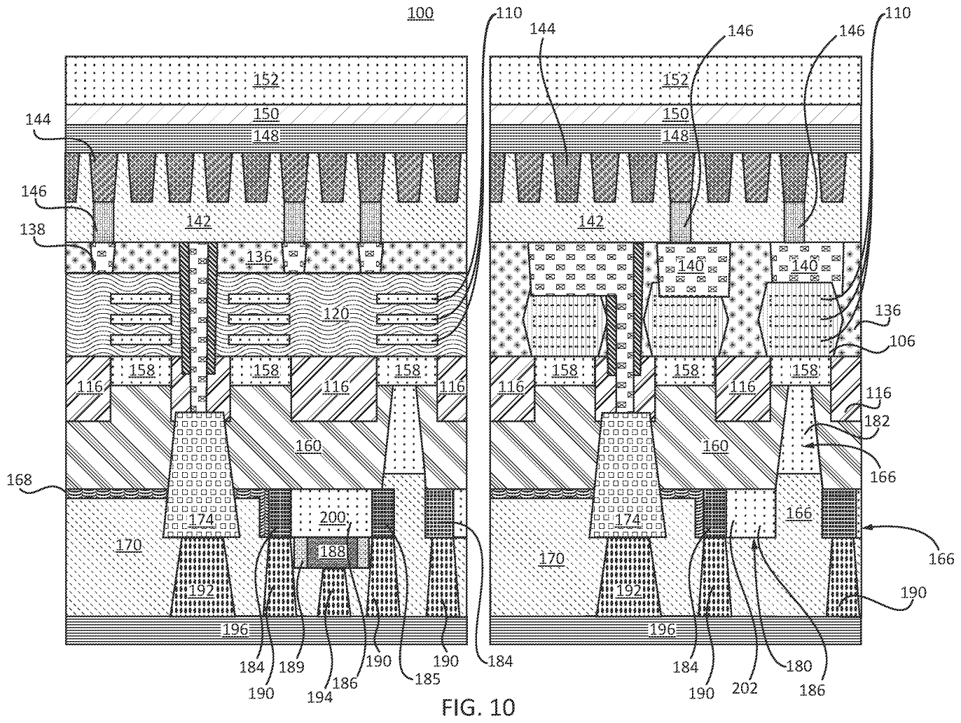

Referring to FIG. 10, the crystallized material 166 can be patterned to separate portions of the crystallized material 166 for the formation of a monolithic device or devices 200, 202. Patterning can be performed using lithography to create an etch mask, and then etch the crystallized material 166 to form the portions for the monolithic device or devices 200, 202. A gate dielectric (not shown, but the passivation layer 168 can be employed as a gate dielectric) can be formed over portions of the crystallized material 166 that will be employed as device channels or junctions through a body 186. A gate conductor 188 is formed over the gate dielectric and patterned to form a gate. Sidewalls spacers 189 can be formed on sidewalls of the gate conductor 188. The sidewall spacers 189 can be formed by depositing a conformal dielectric coating (e.g., SiN) over the gate conductor 188 and then etching in a sidewall spacer etch.

Portions of the crystallized material 166 can be doped to form source regions and drain regions. In an example, source regions 184 and drain regions 185 can be doped using an implantation process, such as ion implantation or other suitable implantation process. The monolithic device 200 includes a FET having a body 186 between the source region 184 and the drain region 185 provides a transistor channel. Other monolithic devices can also be formed. In an example, an electrostatic discharge diode as monolithic device 202 can be formed.

Processing continues with depositing additional dielectric materials to extend the dielectric layer 170. The dielectric layer 170 is patterned and contacts, vias (backside vias (BSV)) and/or interconnects are formed. Backside vias or contacts 190, 192, 194 can be formed by depositing a conductive material into patterned openings in the dielectric layer 170 and planarizing the surface (e.g., by CMP).

The contacts 190 connect to source and drain regions 184, 185. The contact 194 connects to the gate conductor 188. The backside vias or contacts 192 connect to the breakdown voltage vias 174. Silicide liners (not shown) can be employed prior to forming the contacts 190. The backside vias or contacts 190, 192, 194 can include a diffusion barrier (not shown).

A backside interconnect layer 196 is formed and includes dielectric layers and metallization structures that can connect components on the wafer 100. The monolithic device 200, which can include a transistor, is formed at the backside of the wafer 100 in at or near the backside interconnect layer 196. The monolithic device 200 includes crystal structures for the source region 184, drain region 185 and the body 186 (e.g., channel region). The crystal structure can include a monocrystalline Si film having a corresponding gate conductor 188 and an associated source region 184 and drain region 185. The gate conductor 188 can be connected to other components through the contact 194. Source regions 184 and drain region 185 connections can also connect to contacts 190, which connect to the backside interconnect layer 196. The backside interconnect layer 196, in turn, can connect to any frontside or backside conductive structures. The monolithic devices 200, 202 can therefore be connected to any frontside or backside conductive structures.

The monolithic device 200 or 202 can be positioned with great flexibility. In an embodiment, the monolithic device is positioned corresponding to a logic device formed in the FEOL, where the source/drain regions 106 of the logic device can be connected to the backside interconnect layer 196 using the backside vias or contacts 192, the vias 174 and to the source/drain region 106 by the through via 124. The monolithic device 200 is formed in closer proximity to power lines in or near the backside interconnect layer 196. In this way, the monolithic device 200 and/or monolithic device 202 could include applications such as, e.g., power gating, voltage regulation and ESD diode breakdown functions.

An ESD diode breaks down and provides a low-impedance path to redirect current to ground if a threshold voltage of the diode is exceeded. During normal operation, the ESD diode is off and does not interfere with the signal or power passing through a line. Placing the monolithic device 200 and/or monolithic device 202 in a corresponding position (e.g., over a logic device or other device or vertically aligned and separated by a depth between, e.g., FEOL and the backside interconnect layer 196) can reduce wiring and reduce delay times, among other things. The logic device or devices include field effect transistors at the front end of line region which include source/drain regions 106 in contact with the seed material 158. The width of the seed material 158 can be exceeded by the monolithic device 200 or 202 or multiple monolithic devices can be patterned and fabricated as a result of the ability to form a large crystalline island with crystal material 166 on the dielectric layer 160 (FIG. 6).

In an embodiment, the body 186 which can include source and drain regions 184, 185 can include a larger width in a parallel direction to the width of the seed material. Not only can the width be larger, but the depth can be larger as well. The monolithic device or devices 200, 202 have the capability to have a larger footprint than FET devices formed at the front end of the line. The seed material 158 has a same material (e.g., Si) and structure (e.g., predominantly monocrystalline) as the body 186 of the monolithic device since the seed material 158 was employed to initiate crystal growth of the body 186 though at a distant away.

Exemplary applications/uses to which the present invention can be applied include, but are not limited to semiconductor devices. Semiconductor devices can include processors, memory devices, application specific integrated circuits (ASICs), logic circuits or devices, combinations of these and any other circuit device. In such devices, one or more semiconductor devices can be included in a central processing unit, a graphics processing unit, and/or a separate processor- or computing element-based controller (e.g., logic gates, etc.). The semiconductor devices can include one or more on-board memories (e.g., caches, dedicated memory arrays, read only memory, etc.). In some embodiments, the semiconductor devices can include one or more memories that can be on or off board or that can be dedicated for use by a hardware processor subsystem (e.g., ROM, RAM, basic input/output system (BIOS), etc.).

In some embodiments, the semiconductor devices can include and execute one or more software elements. The one or more software elements can include an operating system and/or one or more applications and/or specific code to achieve a specified result. In still other embodiments, the semiconductor devices can include dedicated, specialized circuitry that perform one or more electronic processing functions to achieve a specified result. Such circuitry can include one or more field programmable gate arrays (FPGAs), and/or programmable applications programmable logic arrays (PLAs).

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” “top,” “bottom” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of devices and methods (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
a backside interconnect layer connected to a front end of line region by connections through a backside interlevel dielectric layer disposed between the backside interconnect layer and the front end of line region; and
a monolithic device including a predominantly monocrystalline body disposed within the backside interlevel dielectric layer and contacted on a side opposite the front end of line region, the monolithic device being connected to a front end of line device by a connection through the backside interconnect layer.

2. The semiconductor device as recited in claim 1, wherein the monolithic device includes a field effect transistor.

3. The semiconductor device as recited in claim 2, wherein the field effect transistor includes a two-dimensional channel device.

4. The semiconductor device as recited in claim 1, wherein the monolithic device includes a diode.

5. The semiconductor device as recited in claim 1, wherein the front end of line device includes a logic device, and the logic device and the monolithic device are vertically aligned on different levels.

6. The semiconductor device as recited in claim 1, further comprising seed material in contact with source and drain regions.

7. The semiconductor device as recited in claim 6, wherein the seed material has a same material and structure as the monocrystalline body of the monolithic device.

8. A semiconductor device, comprising:
a front end of line region including field effect transistors and defining a frontside and a backside, opposite the frontside;
a backside interconnect layer connected to the front end of line region by connections through a backside interlevel dielectric layer disposed between the backside interconnect layer and the front end of line region;
a monolithic device including a predominantly monocrystalline body disposed within the backside interlevel dielectric layer, the monolithic device having the body contacted by a contact on a side opposite the front end of line region, the contact connecting to the backside interconnect layer and further connected to a source/drain region in the front end of line region; and
a through via that traverses the front end of line region and connects to the monolithic device through the backside interconnect layer on the backside.

9. The semiconductor device as recited in claim 8, wherein the monolithic device includes a field effect transistor.

10. The semiconductor device as recited in claim 9, wherein the field effect transistor includes a two-dimensional channel device.

11. The semiconductor device as recited in claim 8, wherein the monolithic device includes a diode.

12. The semiconductor device as recited in claim 8, wherein one of the field effect transistors of the front end of line region includes a logic device and the monolithic device is vertically aligned with the logic device but disposed on a different level.

13. The semiconductor device as recited in claim 8, further comprising seed material in contact with source and drain regions in the front end of line region.

14. The semiconductor device as recited in claim 13, wherein the seed material has a same material and structure as the monocrystalline body of the monolithic device.

15. A semiconductor device, comprising:
a front end of line region including field effect transistors, the front end of line region defining a frontside and a backside, opposite the frontside;
the field effect transistors of the front end of line region including a source/drain region in contact with a seed material having a width; and
a monolithic device including a predominantly monocrystalline body disposed in a backside interlevel dielectric layer disposed between a backside interconnect layer and the front end of line region, the monolithic device having a width greater than the width of the seed material.

16. The semiconductor device as recited in claim 15, wherein the field effect transistors of the front end of line region include a logic device and the monolithic device is vertically aligned with the logic device but on a different level.

17. The semiconductor device as recited in claim 15, wherein the seed material is in contact with source and drain regions on the backside.

18. The semiconductor device as recited in claim 15, wherein the seed material has a same material and structure as the monocrystalline body of the monolithic device.

19. The semiconductor device as recited in claim 15, wherein the monolithic device includes a field effect transistor.

20. The semiconductor device as recited in claim 15, wherein the monolithic device includes a diode.
